(19) United States
(12) Patent Application Publication
(10) Pub. No.: US 2024/0213294 A1
(43) Pub. Date: Jun. 27, 2024

(54) MICRO-CAVITY MICRO-LED PIXEL DESIGN WITH DIRECTIONAL EMISSION FOR HIGH EFFICIENCY AR/MR APPLICATIONS

(71) Applicant: MICROSOFT TECHNOLOGY LICENSING, LLC, Redmond, WA (US)

(72) Inventors: Xuzhou LI, Mountain View, CA (US); Ruipeng SUN, Pleasanton, CA (US)

(21) Appl. No.: 18/088,356

(22) Filed: Dec. 23, 2022

(51) Int. Cl. H01L 27/15

(52) U.S. Cl. CPC H01L 27/156

(57) ABSTRACT

Technologies are described for micro-LED devices that employ a resonant micro-cavity structure to promote direction emission. The described techniques facilitate a narrowed emission spectra, with improved optical efficiency and reduced energy consumption. The light emission profiles are collimated by the cavity effect in the LED, yielding improving brightness and significantly reducing the required optical power to achieve the desired brightness. The described resonant micro-cavity structures emit light for certain desired optical modes, while suppressing certain other modes that are not desired. Concave surfaces in the resonance micro-cavity structures may be used to further confine light propagation in the horizontal direction, achieve better collimation, and reduce pixel level crosstalk. Micro-lenses can be used to further enhance the desirable light collimation effects of the described devices.

### BACKGROUND

Mixed Reality (MR), which may include both Augmented Reality (AR) and Virtual Reality (VR), is an industry with a rapidly expanding footprint. An MR device may be implemented with a headset that includes video and audio components to provide the immersive MR experience. An MR device may be implemented in various forms such as a near-eye-display (NED) or head mounted display (HMD) that includes left and right display components as well as left and right audio components.

Pixels are a basic unit of a display image, where a full display image may be formed from an array of pixels. The arrays are typically arranged as a two-dimensional (2D) array, where individual pixels may be addressed by an x-y coordinate system, such as by row and column numbers. In some examples, a single addressable display pixel may correspond to a cluster of LED devices, where each individual LED device may correspond to a different primary color.

Conventional LED devices have various physical properties that may be undesirable. An example conventional LED device may exhibit undesirable characteristics such as a significantly large emission angle. For a given LED drive signal, a large emission angle may be perceived as a loss in pixel brightness or pixel intensity. The large emission angel may also be perceived as a loss of color or contrast between pixels. Although the LED drive signals may be adjusted to compensate for loss in intensity or contrast, there is a negative consequence of increased heat and power consumption in the device.

The disclosure made herein is presented with respect to these and other considerations.

### SUMMARY

Technologies are described herein for micro-LED devices that employ a resonant micro-cavity structure to promote direction emission. The described techniques facilitate a narrowed emission spectra, with improved optical efficiency and reduced energy consumption. The light emission profiles are collimated by the cavity effect in the LED, yielding improving brightness and significantly reducing the required optical power to achieve the desired brightness. The described resonant micro-cavity structures emit light for certain desired optical modes, while suppressing certain other modes that are not desired. Concave surfaces in the resonance micro-cavity structures may be used to further confine light propagation in the horizontal direction, achieve better collimation, and reduce pixel level crosstalk. Micro-lenses can be used to further enhance the desirable light collimation effects of the described devices.

In some examples, a micro-pixel light emitting diode (LED) device is described, comprising: a first contact located about a top contact region of a top portion of the device, wherein the first contact corresponds to one of an n-type material and a p-type material: a distributed Bragg reflector located about an aperture region of the top portion of the device, wherein the aperture region and the top contact region are substantially different from one another: a second contact located about a bottom contact region in a bottom portion of the device, wherein the second contact corresponds to one of the n-type material and a p-type material that is different from the first contact; an optically reflective surface of the second contact; a quantum well located in a central portion of the device between the top portion and the bottom portion: and a resonant micro-cavity formed about the quantum well between the distributed Bragg reflector and the optically reflective surface of the second contact, wherein the distributed Bragg reflector corresponds to a top reflector of the resonant micro-cavity and the optically reflective surface corresponds to a bottom reflector of the resonant micro-cavity, and wherein one or more of the optically reflective surface and the distributed Bragg reflector are concavely shaped such that the resonant micro-cavity promotes vertical light propagation and confines horizontal light propagation.

In some additional examples, a micro-pixel light emitting diode (LED) device is described, comprising: a first contact located about a top contact region in a top portion of the device, wherein the first contact corresponds to one of an n-type material and a p-type material; a distributed Bragg reflector located about an aperture region of the top portion of the device, wherein the aperture region and the top contact region are substantially different from one another: a second contact located about a bottom contact region of a bottom portion of the device, wherein the second contact corresponds to one of the n-type material and a p-type material that is different from the first contact; an optically reflective surface of the second contact; a quantum well located in a central portion of the device between the top portion and the bottom portion; and a micro-lens located above the distributed Bragg reflector; and a resonant micro-cavity formed about the quantum well between the distributed Bragg reflector and the optically reflective surface of the second contact; wherein: the distributed Bragg reflector corresponds to a top reflector of resonant micro-cavity: the optically reflective surface corresponds to a bottom reflector of the resonant micro-cavity: the optically reflective surface is concave with respect to a first focal point (FP1) located along an axis that between the optically reflective surface and the distributed Bragg reflector; the distributed Bragg reflector is concave with respect to a second focal point (FP2) located along the axis; the resonant micro-cavity is configured to promote vertical light propagation and to confine horizontal light propagation: the resonant micro-cavity is configured to promote emission of desired optical modes and suppress emission of other optical modes that are not desired: the resonant micro-cavity is configured to emit collimated light at a surface about the aperture region from the distributed Bragg reflector; and the micro-lens is configured to further collimate the light emitted from the resonant micro-cavity.

In still other examples, a display panel device is described, comprising: an array of micro-pixel light emitting diode devices, wherein each of the micro-pixel light emitting diode devices comprises: a first contact located about a top contact region of a top portion of the device, wherein the first contact corresponds to one of an n-type material and a p-type material; a distributed Bragg reflector located about an aperture region of the top portion of the device, wherein the aperture region and the top contact region are substantially different from one another; a second contact located about a bottom contact region in a bottom portion of the device, wherein the second contact corresponds to one of the n-type material and a p-type material that is different from the first contact; an optically reflective surface of the second contact; a quantum well located in a central portion of the device between the top portion and the bottom portion: and a resonant micro-cavity formed about the quantum well between the distributed Bragg reflector and the optically reflective surface of the second contact, wherein the distributed Bragg reflector corresponds to a top reflector of the resonant micro-cavity and the optically reflective surface corresponds to a bottom reflector of the resonant micro-cavity, and wherein one or more of the optically reflective surface and the distributed Bragg reflector are concavely shaped such that the resonant micro-cavity promotes vertical light propagation and confines horizontal light propagation.

It should be appreciated that the above-described subject matter may also be implemented as part of an apparatus, system, or as part of an article of manufacture. These and various other features will be apparent from a reading of the following Detailed Description and a review of the associated drawings.

This Summary is provided to introduce a selection of concepts in a simplified form that are further described below in the Detailed Description. This Summary is not intended to identify key features or essential features of the claimed subject matter, nor is it intended that this Summary be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

The Detailed Description is described with reference to the accompanying figures. References made to individual items of a plurality of items can use a reference number with a letter of a sequence of letters to refer to each individual item. Generic references to the items may use the specific reference number without the sequence of letters.

FIG. 1 shows a schematic view of an example resonant micro-cavity based micro-LED device with directional emission and high efficiency.

FIG. 2 shows graphs comparing emission profiles achieved with resonant micro-cavity based micro-LED devices.

FIG. 3 shows a 3D view of an example resonant micro-cavity based micro-LED device with direction emission and high efficiency.

FIG. 4 shows a schematic view of another example resonant micro-cavity based micro-LED device with directional emission and high efficiency.

FIG. 5 shows a schematic view of still another example resonant micro-cavity based micro-LED device with directional emission and high efficiency.

FIG. 6 shows a schematic view of yet another example resonant micro-cavity based micro-LED device with directional emission and high efficiency.

FIG. 7 shows a schematic view of still yet another example resonant micro-cavity based micro-LED device with directional emission and high efficiency.

FIG. 8 shows a perspective view of a display device that includes resonant micro-cavity based-LED devices with directional emission and high efficiency.

FIG. 9 shows graphs comparing spectral widths achieved with resonant micro-cavity based micro-LED devices.

### DETAILED DESCRIPTION

In the following detailed description, reference is made to the accompanied drawings, which form a part hereof, and which is shown by way of illustration, specific example configurations of which the concepts can be practiced. These configurations are described in sufficient detail to enable those skilled in the art to practice the techniques disclosed herein, and it is to be understood that other configurations can be utilized, and other changes may be made, without departing from the spirit or scope of the presented concepts. The following detailed description is, therefore, not to be taken in a limiting sense, and the scope of the presented concepts is defined only by the appended claims.

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means a direct electrical connection between the items connected, without any intermediate devices. The term “coupled” means a direct electrical connection between the items connected, or an indirect connection through one or more passive or active intermediary devices and/or components. The terms “circuit” and “component” means either a single component or a multiplicity of components, either active and/or passive, that are coupled to provide a desired function. The term “signal” means at least a power, current, voltage, or data signal.

The term “layer” may refer to a portion of a material that includes a region of thickness. A layer may extend over an entire other layer, or an underlying structure, or may have an extent that is less than the extent of the underlying layer or structure. Additionally, a layer may be a homogeneous region or a heterogeneous region, where the thickness of the region may be varied. In various examples, a layer may include a top surface and a bottom surface of a continuous structure, or a layer may be located between a pair of substantially planar regions. Some layers may correspond to a substantially planar region of material, with a consistent thickness over the planar region. Other example layers may include inclined or stepped regions, with differing thickness over the inclined or stepped regions. The layers may extend horizontally, vertically and/or along a tapered surface. A layer may also be comprised of multiple layers. In some examples, a semiconductor layer may include one or more doped or undoped regions, which may be of the same or different material types.

Semiconductor materials contemplated herein may include any appropriate material, including but not limited to silicon (Si), silicon carbide (SiC), germanium (Ge), gallium nitride (GaN), gallium arsenide (GaAs), gallium phosphide (GaP), indium phosphide (InP), indium gallium nitride (InGaN), aluminum gallium nitride (AlGaN), aluminum gallium indium phosphide (AlGaInP), aluminum, gallium arsenide (AlGaAs), and aluminum indium gallium phosphide (AlInGaP). Non-conductive or insulative materials contemplated herein may include any appropriate material, including but not limited to glass, plastic or sapphire.

Technologies are described herein for micro-LED devices that employ a resonant micro-cavity structure to promote direction emission. The described techniques facilitate a narrowed emission spectra, with improved optical efficiency and reduced energy consumption. The light emission profiles are collimated by the cavity effect in the LED, yielding improving brightness and significantly reducing the required optical power to achieve the desired brightness. The resonant micro-cavity structures emit light for certain desired optical modes, while suppressing certain other modes that are not desired. Concave surfaces in the resonance micro-cavity may be used to further confine light propagation in the horizontal direction, achieve better collimation, and reduce pixel level crosstalk. Micro-lenses can be used to further enhance the desirable light collimation effects of the described devices.

Mixed Reality (AR) devices are an exciting consumer electronics area, which may present the next form factor in portable devices to follow cell phones. A number of large technology companies are investing in this field, e.g., Google, Meta, Apple and Microsoft. One of the key components needed to build a small form-factor glasses style of device is a micro-display, which may be implemented as part as a near-eye-display (NED) device. Micro-LED devices are a next generation display technology that has the potential to provide displays with compact pixel pitch, high brightness, and long lifetime. However, one of the key challenges for Micro-LED technologies is system light utilization efficiency.

In contemplation of the presently disclosed technologies, a conventional LED device was evaluated for use in a micro-sized display. For the conventional LED device, the angular emission profile has a Lambertian shape. With a F #2 based projection lens system, less than about seven percent (<7%) of the total light emitted from the conventional LED can be collected by the lens, passed to the waveguides and presented to the user's eye. The remaining ninety-three percent (>93%) of the total light emitted from the conventional LED is stray-light that is lost, which is perceived by the user as a loss in brightness, color, contrast, etc. To compensate for the inefficiency of a conventional LED, the drive signal levels to the LED are increased, which results in wasted power and increased heat that must be dissipated by the device.

As the F # in the projection lens system is increased, the loss in efficiency increases further still, yielding further undesirable system performance. For example, the low light collection efficiency from the overall system presents problems in overall power consumption, heat dissipation and loss of useful battery life in a portable device such as AR glasses. The present disclosure contemplates these issues and presents a novel Micro-LED based emitter with improved directional emission with increased collimation, which is highly desirable and may improve system efficiency dramatically and make practical AR solutions possible.

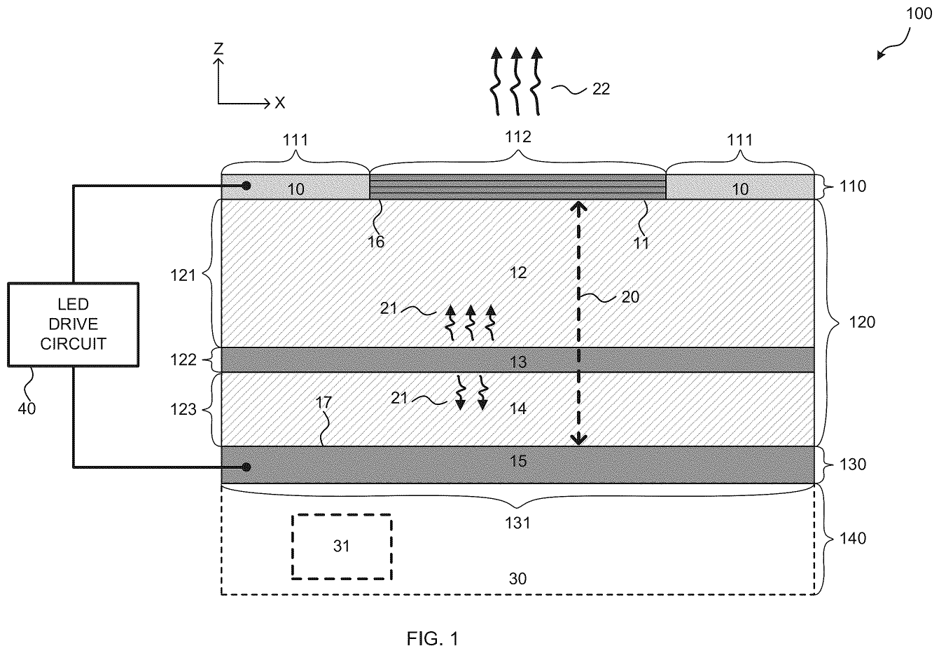

FIG. 1 shows a schematic view of an example resonant micro-cavity based micro-LED device 100 with directional emission and high efficiency, arranged in accordance with aspects of the present disclosure. The micro-LED device 100 may be used as a pixel a display system, and thus is also referred to as a micro-pixel light emitting diode (LED) device.

As shown in FIG. 1, the micro-LED device 100 includes a top portion 110, a bottom portion 130, and a middle or central portion 120 located between the top portion 110 and the bottom portion 130. Each of the portions may be implemented as one or more layers extending over the X-Z plane, where the designations of top, central, and bottom are relative to the Z-axis as shown. Although the example illustrated in FIG. 1 is drawn as a two-dimensional structure (2D) in an X-Z plane, this is merely for convenience of discussion and the device is expected to be implemented as a three-dimensional structure with addition of a Y dimension.

The top portion 110 includes one or more top contact regions 111. A first contact 10 is located about the top contact region 111 of a top portion 110 of the device 100, where the first contact 10 may correspond to either an n-type material or a p-type material (e.g., an n-type or p-type doped silicon material). The material of the first contact 10 effectively forms an electrode or first electrical connection to the device 100. Although an additional contact 10 is also shown in the top contact region 111, this additional contact may be electrically coupled to the first contact 10 so that the contacts 10 together function as a single electrode for the device 100.

The top portion 110 also includes an aperture region 112. A distributed Bragg reflector 11 is located about the aperture region 112 of the top portion 110 of the device 100. The aperture region 112 and the top contact region 111 are substantially different from one another, although in some examples there may be some nominal overlap between regions 111 and 112.

A distributed Bragg reflector (DBR) is a structure formed from multiple layers of alternating materials with varying refractive indices, or by a periodic variation of some other characteristic of a dielectric waveguide. The alternating materials provide optical boundary conditions with periodic variations in the effective refractive index, which results in a high-quality reflector. For a range of wavelengths, the DBR has a very high reflectivity, where the DBR effectively blocks propagation of certain modes (e.g., TE modes) in the structure, while promoting propagation of certain other modes (e.g., TM modes) in the structure. In some examples, a DBR may be constructed by stacking layers of materials such as titanium dioxide, with a refractive index of about 2.5, and silica, with a refractive index of about 1.5), but many other materials are also contemplated.

The bottom portion 130 includes a bottom contact region 131. A second contact 15 is located about the bottom contact region 131 in the bottom portion 130 of the device 100. The second contact 15 corresponds to one of the n-type material and a p-type material that is different from the first contact 10. For example, if the first contact 10 is an n-type material then the second contact 15 will be a p-type material, or vice-versa. The material of the second contact 15 effectively forms another electrode or second electrical connection to the device 100.

The central portion 120 includes a middle region 122, which is located between an upper region 121 and a lower region 123. The upper 121 region of the central portion 120 may correspond to a semiconductor material 12 of a first type (e.g., n-type or p-type), while the lower region 123 of the central portion 120 may correspond a semiconductor material 14 of a second type (e.g., p-type or n-type), which is an opposite of the first type from the upper region 121. The materials used for the upper and lower regions may generally be of the same type of material (e.g., Aluminum Arsenide), but of differing doping configurations for positive or negative types. The middle region 121 may correspond to a quantum well 13 formed from another semiconductor material (e.g., Gallium Arsenide), which may also be referred to as an active region of the device 100. The semiconductor material of the quantum well 13 has a lower energy bandgap then the surrounding semiconductor materials 12 and 14, which have a wider energy bandgap.

In some examples, the quantum well 13 may be formed as a superlattice or periodic structure of alternating materials. The energy bandgap characteristics of the periodic structure results in a periodic series of quantum wells, referred to as a multiple quantum well (MQW), where the barriers between adjacent wells are thick enough to prevent adjacent wave functions from coupling.

The second contact 15 may further include an optically reflective surface 17 that is facing upwards (relative to the Z-direction) towards a corresponding reflective surface 16 of the distributed Bragg reflector 11. Thus, the surface 16 of the distributed Bragg reflector 11 corresponds to a top reflector of a resonant micro-cavity 20, while the optically reflective surface 17 of the second contact 15 corresponds to a bottom reflector of the resonant micro-cavity 20. The optically reflective surface 17 of the second contact 15 may be formed of a high reflectivity metal or metal alloy (e.g., Aluminum, Silver, Titanium, Zinc, Magnesium, etc.).

Device 100 illustrates a Micro-LED pixel structure, which includes a distributed Bragg reflector (DBR) on the top reflective surface or mirror 16 at the first contact side, and an optically reflective material (e.g., Silver/Aluminum reflector) or mirror 17 on the bottom contact side. The two reflectors 16 and 17 together provide an optical resonant micro-cavity 20 for the micro-LED pixel.

Operationally, drive electronics such as an LED drive circuit 40 may be coupled to the first and second electrodes formed at the first contact 10 and the second contact 15. In some examples, the LED drive circuit 40 may be located separate from the LED devices. In some other examples, another LED drive circuit 31 may be located in a lower region 140 of a substrate 30, which may be integrated together with the LED devices as shown in FIG. 1.

The micro-LED device is biased into active operation by the drive signals, and light 21 is emitted from the quantum well 13 (or multiple quantum well will, MQW) in the active region of the device 100. The emitted light 21 results in interference in the resonance cavity, where certain optical modes are easily coupled through the distributed Bragg reflector 11 and output as light 22, and some other optical modes are suppressed from output. Overall, a more collimated angular emission profile, which is highly directional, is generated by the disclosed device 100.

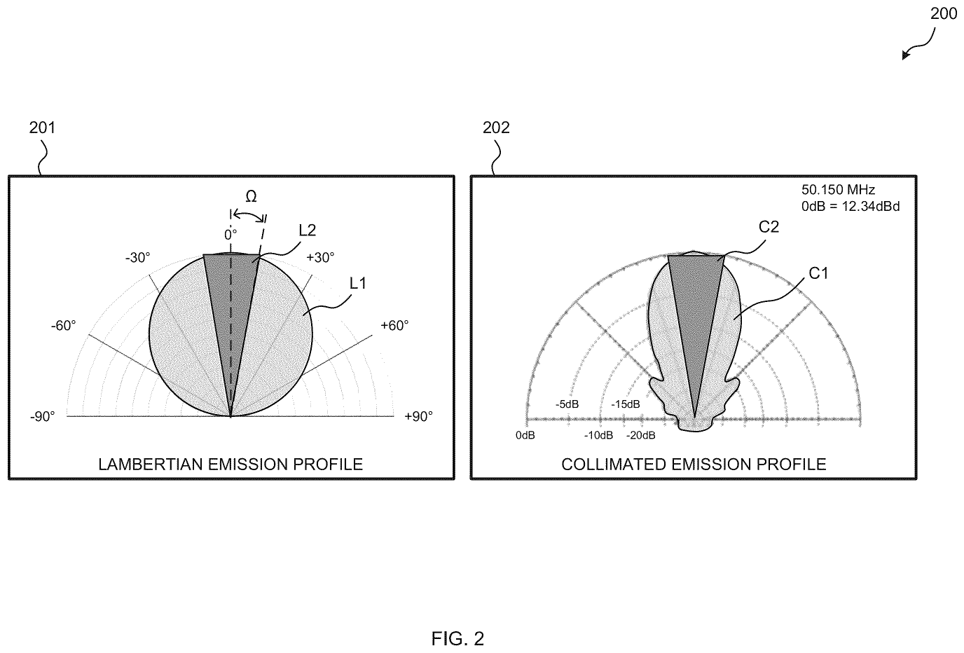

FIG. 2 shows graphs 201 and 202 comparing emission profiles achieved with resonant micro-cavity based micro-LED devices such as device 100 of FIG. 1. The first graph 201 illustrates an emission profile for a conventional LED device, while the second graph 202 illustrates an emission profile for the improved LED devices described herein.

Optical efficiency is an important feature of a panel display. Not all of the light that is emitted from a light source is effective for illumination. Accordingly, the beam formed by the center cone angle (e.g., Ω=±10°/±15) is the dominant light that propagates through the projection system. As a result of this characteristic, for emitters with a broad emission angle, a large portion of the emitted light is lost, and the effective optical efficiency of the system is greatly reduced.

As shown in the first graph 201, a conventional LED device presents a Lambertian emission profile, where the total optical power emitted is shown by area L1 and the useful optical power is shown by the smaller area L2. The overall percentage of useful optical power to be collected by a lens (e.g., F #2 lens system) corresponds to less than about 7% of the total area.

As shown in the second graph 202, an improved LED device presents a highly directional emission profile, where the light is approximately collimated. For this example, the total optical power emitted is shown by area C1, while the useful optical power is shown by the area C2. Although the collection cone area is substantially the same for graphs 201 and 202, the overall percentage of useful optical power that is collected by a lens (e.g., F #2 lens system) in this example corresponds to about 15-25% of the total area, which is more than a doubling of the useful optical power when compared to the convention LED device. Thus, the presently disclosed devices such as device 100 exhibit collimated light emission characteristics, where optical efficiency into the center cone angle region is increased and more optical energy is delivered to each pixel.

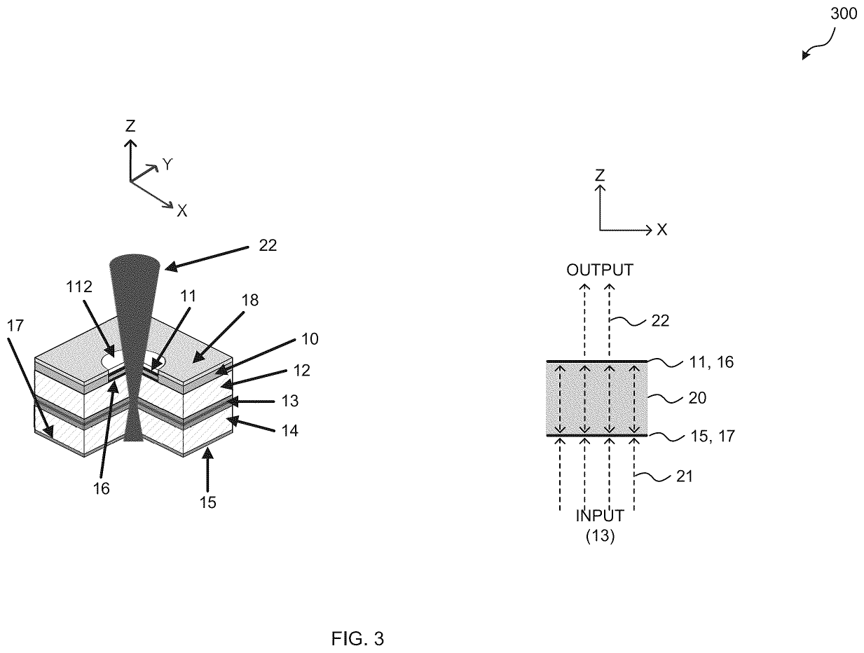

FIG. 3 shows a 3D view of an example resonant micro-cavity based micro-LED device 300 with direction emission and high efficiency, arranged in accordance with aspects of the present disclosure. Like parts from FIG. 1 are labelled identically.

As shown in FIG. 3, device 300 includes an upper portion with a first contact 10 and an aperture region 112 with a distributed Bragg reflector 11 with a reflective surface 16, a middle portion with semiconductor materials 12 and 14 surrounding a quantum well 13, and a lower portion with a second contact 15 and an optically reflective surface 17.

The device 300 may further includes an isolation layer 18 (e.g., ITO), which may be referred to as an oxide layer. The aperture region 112 may correspond to an aperture in the isolation layer (e.g., an oxide aperture). As shown, the first contact 10 is positioned in a three dimensional continuous region that substantially surrounds the aperture region 112, where the distributed Bragg reflector 11 is located.

As illustrated in FIG. 3, an optically resonant micro-cavity 20 is formed around the quantum well 13 by a top reflector surface 16 of the distributed Bragg reflector 11 and the bottom reflector surface 17 of the bottom contact 15. When the device 300 is activated by applying a bias or drive signal across the first contact 10 and the second contact 15, the quantum well 13 emits light 21, which is input into the optically resonant microcavity 20. Certain modes are trapped in the micro-cavity, while other modes are transmitted and output through the aperture region 112 of the distributed Bragg reflector as emitted light 22.

The illustrated optical cavity 20 has similar properties to a Fabry-Perot cavity. In particular, the resonance of the cavity formed by the upper mirror 16 and lower mirror 17 of the distributed Bragg reflector 11 and the bottom contact 15 provides significantly confinement of horizontal emission, and promotes a confined angular emission profile with a narrowed emission spectra through the distributed Bragg reflector 11. Light at resonant wavelengths and desired modes is output through the distributed Bragg reflector 11, while other non-resonant wavelengths and undesired modes are blocked from emission from the device. The distributed Bragg reflector may thus be configured to emit light from the resonant micro-cavity at a surface about the aperture region 112.

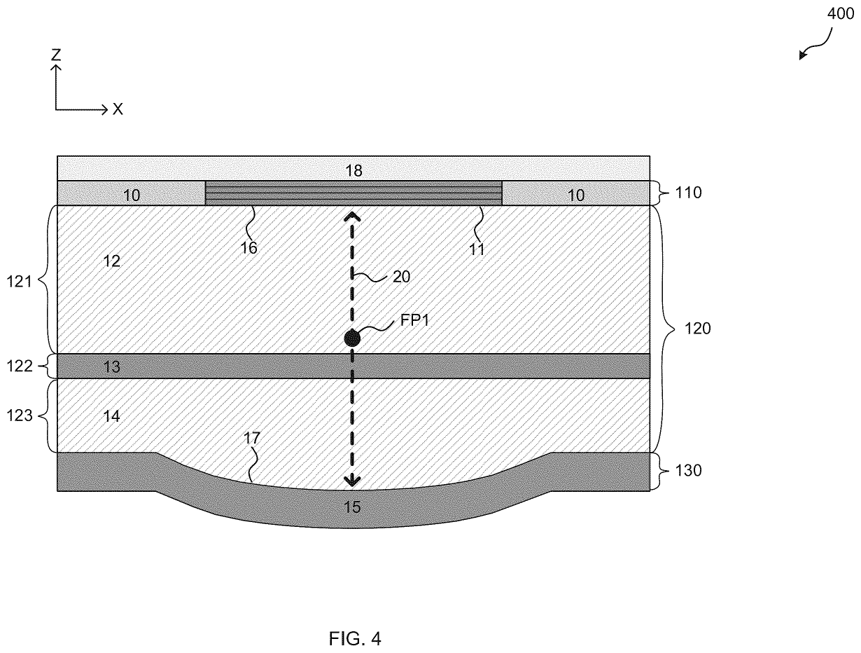

FIG. 4 shows a schematic view of another example resonant micro-cavity based micro-LED device 400 with directional emission and high efficiency, arranged in accordance with additional aspects of the present disclosure. Like parts from FIGS. 1 and 3 are labelled identically.

As shown in FIG. 4, device 400 includes an upper portion 110 with a first contact 10 and an aperture region with a distributed Bragg reflector 11 and a reflective surface 16, a middle portion 120 with semiconductor materials 12 and 14 in upper region 121 and lower region 122 surrounding a quantum well 13 in a middle region 122, a lower portion 130 with a second contact 15 and an optically reflective surface 17, and an isolation layer 18 (e.g., ITO).

For the device 400 in FIG. 4, the bottom contact 15 has a generally concave shape with respect to a first focal point (FP1) along an axis of the resonance cavity, which extends between the optically reflective surface 17 and the distributed Bragg reflector 11. The concave shape of the lower or bottom reflector 17 formed on the bottom contact 15 enhances the performance of the optical resonant cavity with better mode confinement, and thus further improves directionality of emission and collimation of emitted light.

The concave shaped optically reflective surface 17 may be of any appropriate reflective material, including but not limited to one or more of: silver, aluminum, gold, platinum, tungsten, copper, nickel, zinc, or alloys thereof. In one example, the bottom contact 15 is made of a p-type material and the optically reflective surface 17 may be formed from a silver material that is deposited on the surface through any appropriate method (e.g., chemical vapor deposition, etching, etc.). In another example, the optically reflective surface may correspond to another distributed Bragg reflector.

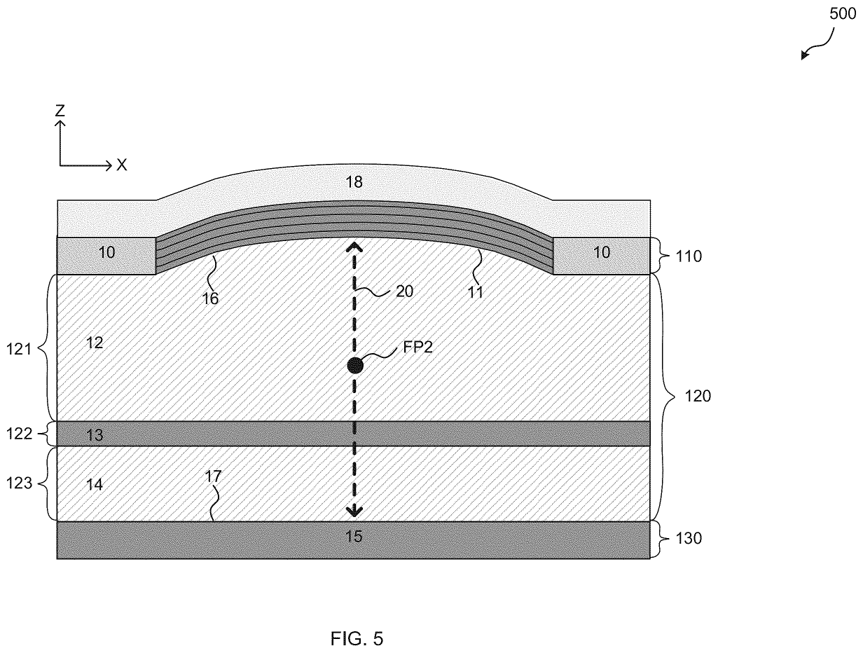

FIG. 5 shows a schematic view of still another example resonant micro-cavity based micro-LED device 500 with directional emission and high efficiency, arranged in accordance with additional aspects of the present disclosure. Like parts from FIGS. 1, 3 and 4 are labelled identically.

As shown in FIG. 5, device 500 includes an upper portion 110 with a first contact 10 and an aperture region with a distributed Bragg reflector 11 and a reflective surface 16, a middle portion 120 with semiconductor materials 12 and 14 in upper region 121 and lower region 122 surrounding a quantum well 13 in a middle region 122, a lower portion 130 with a second contact 15 and an optically reflective surface 17, and an isolation layer 18 (e.g., ITO).

For the device 500 in FIG. 5, the distributed Bragg reflector 11 has a generally concave shape with respect to a second focal point (FP1) along an axis of the resonance cavity, which extends between the distributed Bragg reflector 11 and the optically reflective surface 17 of the bottom contact 15. The concave shape of the upper or top reflector 16 formed on the distributed Bragg reflector 11 enhances the performance of the optical resonant cavity with better mode confinement, and thus further improves directionality of emission and collimation of emitted light.

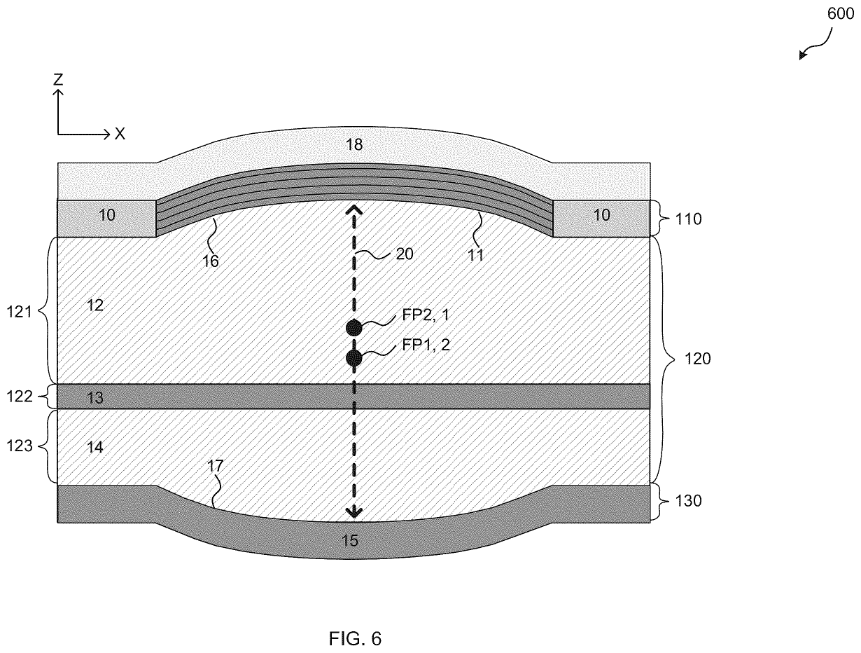

FIG. 6 shows a schematic view of yet another example resonant micro-cavity based micro-LED device 600 with directional emission and high efficiency, arranged in accordance with additional aspects of the present disclosure. Like parts from FIGS. 1, 3, 4, and 5 are labelled identically.

As shown in FIG. 6, device 600 includes an upper portion 110 with a first contact 10 and an aperture region with a distributed Bragg reflector 11 and a reflective surface 16, a middle portion 120 with semiconductor materials 12 and 14 in upper region 121 and lower region 122 surrounding a quantum well 13 in a middle region 122, a lower portion 130 with a second contact 15 and an optically reflective surface 17, and an isolation layer 18 (e.g., ITO).

For the device 600 in FIG. 6, the optically reflective surface 17 is concave with respect to a first focal point (FP1) located along an axis that extends between the optically reflective surface 17 and the distributed Bragg reflector 11, and the distributed Bragg reflector 11 has a concave reflective surface with respect to a second focal point (FP2) located along the axis of the resonance cavity 20. The concave shape of the upper or top reflector 16 and the lower or bottom reflector 17 together enhance the performance of the optical resonant cavity 20 with even better mode confinement, and thus further improves directionality of emission and collimation of emitted light.

The specific location of the illustrated focal points (FP1, FP2) for the concave shapes of the reflectors may be adjusted based on the desired wavelengths and modes to be promoted in the resonance cavity. As such, focal points FP1 and FP2 may be the same focal point, or different focal points, and their specific location may be swapped or moved as may be required to result in a desired interference pattern for promotion or suppression of specific wavelengths and/or modes.

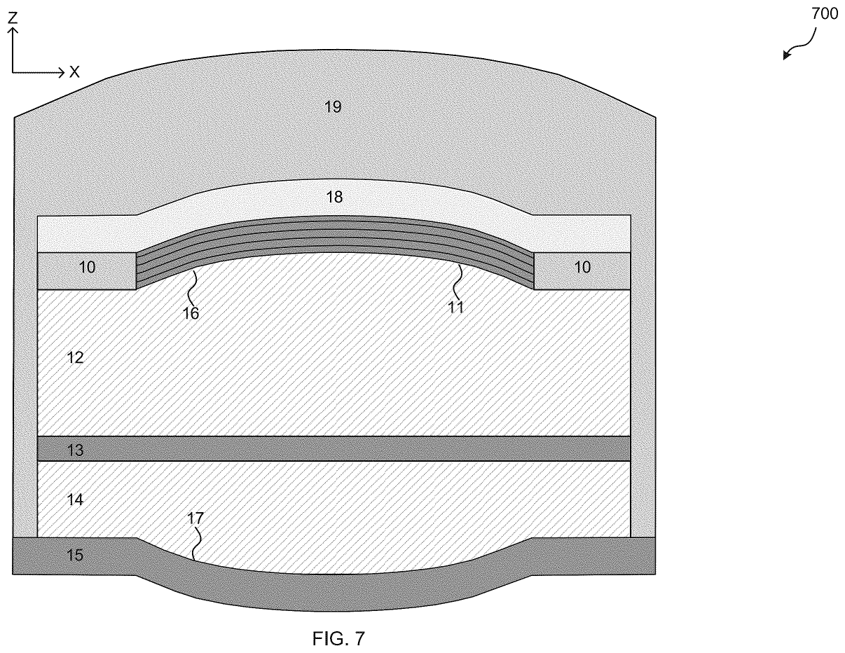

FIG. 7 shows a schematic view of still yet another example resonant micro-cavity based micro-LED device with directional emission and high efficiency, arranged in accordance with additional aspects of the present disclosure. Like parts from FIGS. 1, 3, 4, 5, and 6 are labelled identically.

As shown in FIG. 7, device 700 includes an upper portion 110 with a first contact 10 and an aperture region with a distributed Bragg reflector 11 and a reflective surface 16, a middle portion 120 with semiconductor materials 12 and 14 in upper region 121 and lower region 122 surrounding a quantum well 13 in a middle region 122, a lower portion 130 with a second contact 15 and an optically reflective surface 17, and an isolation layer 18 (e.g., ITO).

For the device 600 in FIG. 6, the optically reflective surface 17 is concave with respect to a first focal point (FP1) located along an axis that extends between the optically reflective surface 17 and the distributed Bragg reflector 11, and the distributed Bragg reflector 11 has a concave reflective surface with respect to a second focal point (FP2) located along the axis of the resonance cavity 20. Additionally, a micro-lens structure 19 is illustrated as being located on top of the emission surface of the device. The concave shape of the upper or top reflector 16 and the lower or bottom reflector 17 together enhance the performance of the optical resonant cavity 20 with improved mode confinement, while the micro-lens 19 further collimates the emitted light from the top surface, and thus further improves directionality of emission and collimation of emitted light.

The specific location of the illustrated focal points (FP1, FP2) for the concave shapes of the reflectors may be adjusted based on the desired wavelengths and modes to be promoted in the resonance cavity. As such, focal points FP1 and FP2 may be the same focal point, or different focal points, and their specific location may be swapped or moved as may be required to result in a desired interference pattern for promotion or suppression of specific wavelengths and/or modes. Thus, the resonant micro-cavity may be arranged to emit light corresponding to desired optical modes while suppressing other optical modes that are not desired.

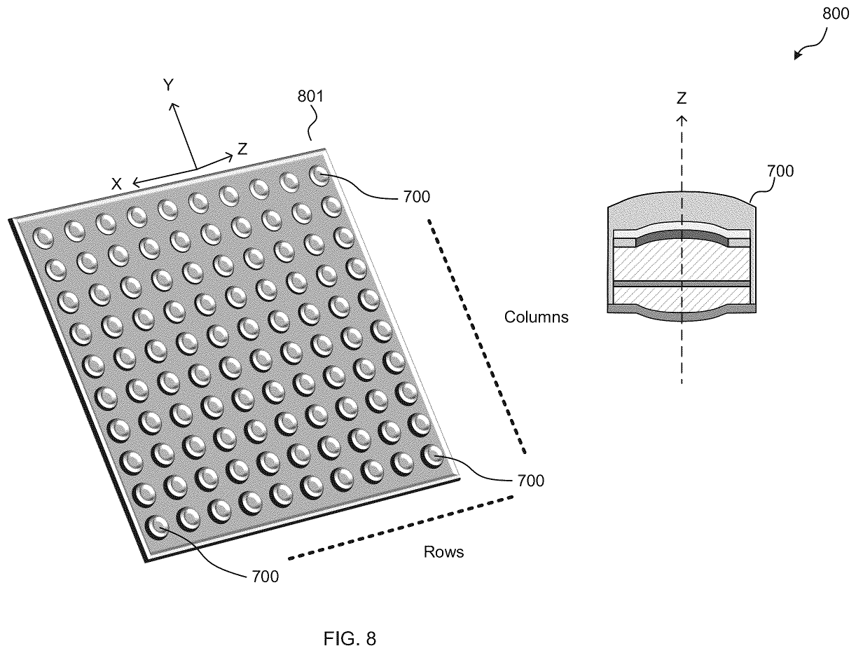

FIG. 8 shows a perspective view of a display device 800 that includes resonant micro-cavity based-LED devices 700 in a micro-display panel 801, arranged in accordance with aspects of the present disclosure. As shown in FIG. 8, the micro-cavity based LED devices 700 are in a two-dimensional (2D) array, with rows of devices shown along a Y-axis and columns of devices shown along an X-axis.

Although devices 700 are shown, corresponding to the same labelling convention as FIG. 7, the implementation is not so limited and any of the previously described devices of FIGS. 1, 3, 4, 5, and 6 are equally applicable. Thus, device 700 may include an upper portion 110 with a first contact 10 and an aperture region with a distributed Bragg reflector 11 and a reflective surface 16, a middle portion 120 with semiconductor materials 12 and 14 in upper region 121 and lower region 122 surrounding a quantum well 13 in a middle region 122, a lower portion 130 with a second contact 15 and an optically reflective surface 17, and an isolation layer 18 (e.g., ITO).

Device 700 may thus optionally include one or more curved surface for the upper or lower reflectors as described for FIGS. 4, 5 and 6. Thus, the display panel 801 may include a 2D array of devices, where each device in the array has one or more of the optically reflective surface 17 and the distributed Bragg reflector 11 concavely shaped so that the resonant micro-cavity promotes vertical light propagation and confines horizontal light propagation.

Additionally, some examples may optionally include a micro-lens as described with respect to FIG. 7. The display panel 801 may thus include a 2D array of devices, where each device in the array includes a micro-lens located above the distributed Bragg reflector 11 about a surface of the aperture region 112 of the device so that the micro-lens is configured to collimate light emitted by the distributed Bragg reflector 11.

In additional examples, the resonant micro-cavity 20 of each of the micro-pixel light emitting diode devices 700 can be arranged to emit light corresponding to desired optical modes while suppressing other optical modes that are not desired as described previously herein.

Some examples of display panel devices 801 may include localized clusters of the micro-pixel light emitting diode devices in the array corresponds to a single pixel of the display panel device. In one example, two adjacent LED devices in the array may correspond to a single addressable pixel, where the intensity of the pixel is effectively doubled by the two LED devices being simultaneously activated.

In another example, three or four adjacent LED devices in the array of the display panel 801 may correspond to a single addressable pixel, where each localized cluster includes at least one micro-pixel light emitting diode device corresponding to each of the primary colors of red, green and blue.

In still other examples, a display pane 801 may correspond to an array of individual LED devices that are manufactured or arranged as part of a single substrate 30. The substrate 30 may further include integrated LED drive electronics 31 or electrical interconnect to facilitate connections to externally located LED drive electronics 40.

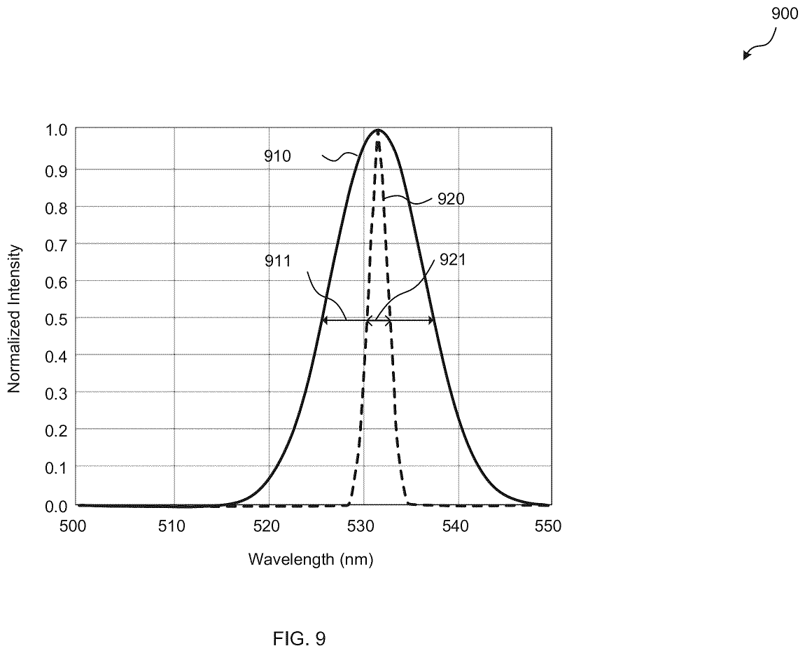

FIG. 9 shows graphs 900 comparing spectral widths achieved with resonant micro-cavity based micro-LED devices, arranged in accordance with various aspects described herein. A conventional LED device, such as a Lambertian profile device, is illustrate by graph 910, which has a nominal wavelength in a range from about 515 nm to about 550 nm, and a normalized intensity with a full-width-half-maximum (FWHM) value of about 30 nm. An improved LED device as described herein is illustrated by graph 9201, which has a nominal wavelength in a range from about 528 nm to about 535 nm, and a normalized intensity with a full-width-half-maximum (FWHM) value of less than about 15 nm, which means better color purity and the ability to achieve larger display color gamut.

Micro-cavity resonance performance can be improved by employing the techniques described herein. Thus, use of concave surfaces 16 on the distributed Bragg reflector 11 and/or concave optically reflective surfaces 17 on the bottom contact 15 may be employed to enhance confinement of light propagation in the horizontal direction, and also to improve the forward emission coupling and reduce pixel-wise crosstalk between adjacent pixels in a display panel (e.g., panel 801 of FIG. 8).

For the micro-LED emission, typical full-width-half-maximum (FWHM) is ˜30 nm. With resonance micro-cavity, the FWHM can be reduced to <15 nm which means better color purity and the potential to achieve larger display color gamut.

The proposed solutions described herein yield systems with optical collection efficiency improvements of greater than fifty percent (>50%), where the FWHM of the micro-LED emission spectra can be reduced to less than fifteen nano-meters (<15 nm).

In one example experiment performed in contemplation of the present disclosure, a double planar Fabry-Perot cavity design was employed. For this example, a MQW device layer was formed in a Gallium Nitride (GaN) substrate, with two pairs of distributed Bragg reflectors used as the top reflector 16, and a silver mirror surface was used for the lower reflector 17 on a p-type bottom contact 15. Each pair of distributed Bragg reflectors had the following characteristics: n1=3.5, thickness of 38 nm; n2=1.5, thickness of 88.7 nm. For this example, a light extraction efficiency of 21.7% was achieved with an angle collection ratio of 15.92%, compared to a Lambertian profile with a light extraction efficiency of only 7%.

In another example experiment performed in contemplation of the present disclosure, a concave planar Fabry-Perot cavity design was employed. For this example, a MQW device layer was again formed in a Gallium Nitride (GaN) substrate, with two pairs of distributed Bragg reflectors used as the top reflector 16, and a concave silver mirror surface was used for the lower reflector 17 on a p-type bottom contact 15. Each pair of distributed Bragg reflectors again had the following characteristics: n1=3.5, thickness of 38 nm; n2=1.5, thickness of 88.7 nm. For this example, the concave surface of the lower reflector 17 had a width of 3 μm and a maximum depth of 1.2 μm. For this example, a light extraction efficiency of 24% was achieved with an angle collection ratio of 20.45%, compared to a Lambertian profile with a light extraction efficiency of only 7%.

Various technical differences are observed between conventional LED devices and the presently described solutions have been demonstrated herein, which achieve many benefits. In one example, conventional devices do not utilize the disclosed resonance of a micro-cavity as is found in the presently disclosed devices, which has been demonstrated to improve emission directionality and spectral bandwidth. In another example, conventional devices do not employ the lower contact as a mirror device, which creates a collimated light emission profile by exploiting the cavity effect in the presently disclosed solutions. Concave resonance micro-cavity designs described herein, including upper or lower reflector designs, enhances confinement of light propagation in the horizontal direction and achieves better propagation in the vertical direction with better collimation and reduce pixel level crosstalk.

With the same projection optics as found in a conventional device, the presently described devices may achieve more than fifty percent (>50%) increased useful optical power from the micro-LED, compared to a Lambertian emitter. To achieve a certain front eye brightness, the LED driving power can thus be reduced by greater than fifty percent (>50%), significantly improving heat dissipation and extending battery life in the systems (e.g., AR/MR systems). Narrower emission spectrum is achieved: where the full-width-half-maximum of the emission spectra will be reduced so that the color purity of the microLED is improved, and a larger overall color gamut of the display can be achieved.

The above specification, examples and data provide a complete description of the manufacture and use of the composition of the invention. Since many embodiments of the invention can be made without departing from the spirit and scope of the invention, the invention resides in the claims hereinafter appended.

The example clauses are to supplement the present disclosure.

Clause A: A micro-pixel light emitting diode (LED) device (100), comprising: a first contact (10) located about a top contact region (111) of a top portion (110) of the device (100), wherein the first contact (10) corresponds to one of an n-type material and a p-type material: a distributed Bragg reflector (11) located about an aperture region (112) of the top portion (110) of the device (100), wherein the aperture region (112) and the top contact region (111) are substantially different from one another; a second contact (15) located about a bottom contact region (131) in a bottom portion (130) of the device (100), wherein the second contact (15) corresponds to one of the n-type material and a p-type material that is different from the first contact (10): an optically reflective surface (17) of the second contact; a quantum well (13) located in a central portion (120) of the device between the top portion (110) and the bottom portion (130); and a resonant micro-cavity (20) formed about the quantum well (13) between the distributed Bragg reflector (11) and the optically reflective surface (17) of the second contact (15), wherein the distributed Bragg reflector (11) corresponds to a top reflector (16) of the resonant micro-cavity (20) and the optically reflective surface (17) corresponds to a bottom reflector of the resonant micro-cavity (20), and wherein one or more of the optically reflective surface (17) and the distributed Bragg reflector (11) are concavely shaped such that the resonant micro-cavity (20) promotes vertical light propagation and confines horizontal light propagation.

Clause B: The device of any of the preceding clauses, wherein the quantum well corresponds to a multiple quantum well (MQW).

Clause C: The device of any of the preceding clauses, wherein the resonant micro-cavity corresponds to a Fabry-Perot cavity.

Clause D: The device of any of the preceding clauses, wherein the first contact corresponds to an n-type material, and the second contact corresponds to a p-type material.

Clause E: The device of any of the preceding clauses, wherein the first contact corresponds to a p-type material, and the second contact corresponds to an n-type material.

Clause F: The device of any of the preceding clauses, wherein the distributed Bragg reflector is configured to emit light from the resonant micro-cavity at a surface about the aperture region.

Clause G: The device of any of the preceding clauses, wherein the optically reflective surface is concave with respect to a focal point located along an axis that extends between the optically reflective surface and the distributed Bragg reflector.

Clause H: The device of any of the preceding clauses, wherein the distributed Bragg reflector is concave with respect to a focal point located along an axis that extends between the distributed Bragg reflector and the optically reflective surface.

Clause I: The device of any of the preceding clauses, wherein the optically reflective surface is concave with respect to a first focal point located along an axis that extends between the optically reflective surface and the distributed Bragg reflector, and wherein the distributed Bragg reflector is concave with respect to a second focal point located along the axis.

Clause J: The device of any of the preceding clauses, the optically reflective surface comprising a reflective material corresponding to one or more of: silver, aluminum, gold, platinum, tungsten, copper, nickel, zinc, or alloys thereof.

Clause K: The device of any of the preceding clauses, wherein the optically reflective surface corresponds to another distributed Bragg reflector.

Clause L: The device of any of the preceding clauses, further comprising a micro-lens located above the distributed Bragg reflector about a surface of the aperture region of the device, wherein the micro-lens is configured to collimate light emitted by the distributed Bragg reflector.\

Clause M: The device of any of the preceding clauses, wherein the resonant micro-cavity is arranged to emit light corresponding to desired optical modes while suppressing other optical modes that are not desired.

Clause N: A micro-pixel light emitting diode (LED) device (700), comprising: a first contact (10) located about a top contact region (111) in a top portion (110) of the device (700), wherein the first contact (10) corresponds to one of an n-type material and a p-type material: a distributed Bragg reflector (11) located about an aperture region (112) of the top portion of the device, wherein the aperture region (112) and the top contact region (111) are substantially different from one another; a second contact (15) located about a bottom contact region (131) of a bottom portion (130) of the device, wherein the second contact (15) corresponds to one of the n-type material and a p-type material that is different from the first contact (10); an optically reflective surface (17) of the second contact (15): a quantum well (13) located in a central portion (120) of the device between the top portion (110) and the bottom portion (130); and a micro-lens (19) located above the distributed Bragg reflector (11); and a resonant micro-cavity (20) formed about the quantum well (13) between the distributed Bragg reflector (11) and the optically reflective surface (17) of the second contact (15); wherein: the distributed Bragg (11) reflector corresponds to a top reflector of resonant micro-cavity (20): the optically reflective surface (17) corresponds to a bottom reflector of the resonant micro-cavity (20); the optically reflective surface (17) is concave with respect to a first focal point (FP1) located along an axis that between the optically reflective surface (17) and the distributed Bragg reflector (11); the distributed Bragg reflector (11) is concave with respect to a second focal point (FP2) located along the axis: the resonant micro-cavity (20) is configured to promote vertical light propagation and to confine horizontal light propagation: the resonant micro-cavity (20) is configured to promote emission of desired optical modes and suppress emission of other optical modes that are not desired: the resonant micro-cavity (20) is configured to emit collimated light at a surface about the aperture region (112) from the distributed Bragg reflector (11); and the micro-lens (19) is configured to further collimate the light emitted from the resonant micro-cavity (20).

Clause O: A display panel device (801), comprising: an array of micro-pixel light emitting diode devices, wherein each of the micro-pixel light emitting diode devices comprises: a first contact (10) located about a top contact region (111) of a top portion (110) of the device (100), wherein the first contact (10) corresponds to one of an n-type material and a p-type material: a distributed Bragg reflector (11) located about an aperture region (112) of the top portion (110) of the device (100), wherein the aperture region (112) and the top contact region (111) are substantially different from one another: a second contact (15) located about a bottom contact region (131) in a bottom portion (130) of the device (100), wherein the second contact (15) corresponds to one of the n-type material and a p-type material that is different from the first contact (10): an optically reflective surface (17) of the second contact; a quantum well (13) located in a central portion (120) of the device between the top portion (110) and the bottom portion (130); and a resonant micro-cavity (20) formed about the quantum well (13) between the distributed Bragg reflector (11) and the optically reflective surface (17) of the second contact (15), wherein the distributed Bragg reflector (11) corresponds to a top reflector (16) of the resonant micro-cavity (20) and the optically reflective surface (17) corresponds to a bottom reflector of the resonant micro-cavity (20), and wherein one or more of the optically reflective surface (17) and the distributed Bragg reflector (11) are concavely shaped such that the resonant micro-cavity (20) promotes vertical light propagation and confines horizontal light propagation.

Clause P: The display panel device of claim any of the preceding clauses, wherein each of the micro-pixel light emitting diode devices includes a micro-lens located above the distributed Bragg reflector about a surface of the aperture region of the device, wherein the micro-lens is configured to collimate light emitted by the distributed Bragg reflector.

Clause Q: The display panel device of claim any of the preceding clauses, wherein the resonant micro-cavity of each of the micro-pixel light emitting diode devices is arranged to emit light corresponding to desired optical modes while suppressing other optical modes that are not desired.

Clause R: The display panel device of claim any of the preceding clauses, wherein localized clusters of the micro-pixel light emitting diode devices in the array corresponds to a single pixel of the display panel device.

Clause S: The display panel device of claim any of the preceding clauses, wherein each localized clusters includes at least one micro-pixel light emitting diode device corresponding to each of the primary colors of red, green and blue.

Clause T: The display panel device of claim any of the preceding clauses, further comprising a single substrate, wherein the array of micro-pixel light emitting diode devices is on the single substrate.

In closing, although the various configurations have been described in language specific to structural features and/or methodological acts, it is to be understood that the subject matter defined in the appended representations is not necessarily limited to the specific features or acts described. Rather, the specific features and acts are disclosed as example forms of implementing the claimed subject matter.

What is claimed is:

1. A micro-pixel light emitting diode (LED) device, comprising:
a first contact located about a top contact region of a top portion of the device, wherein the first contact corresponds to one of an n-type material and a p-type material;
a distributed Bragg reflector located about an aperture region of the top portion of the device, wherein the aperture region and the top contact region are substantially different from one another;
a second contact located about a bottom contact region in a bottom portion of the device, wherein the second contact corresponds to one of the n-type material and a p-type material that is different from the first contact;
an optically reflective surface of the second contact;
a quantum well located in a central portion of the device between the top portion and the bottom portion; and
a resonant micro-cavity formed about the quantum well between the distributed Bragg reflector and the optically reflective surface of the second contact, wherein the distributed Bragg reflector corresponds to a top reflector of the resonant micro-cavity and the optically reflective surface corresponds to a bottom reflector of the resonant micro-cavity, and wherein one or more of the optically reflective surface and the distributed Bragg reflector are concavely shaped such that the resonant micro-cavity promotes vertical light propagation and confines horizontal light propagation.

2. The device of claim 1, wherein the quantum well corresponds to a multiple quantum well (MQW).

3. The device claim of 1, wherein the resonant micro-cavity corresponds to a Fabry-Perot cavity.

4. The device of claim 1, wherein the first contact corresponds to an n-type material, and the second contact corresponds to a p-type material.

5. The device of claim 1, wherein the first contact corresponds to a p-type material, and the second contact corresponds to an n-type material.

6. The device of claim 1, wherein the distributed Bragg reflector is configured to emit light from the resonant micro-cavity at a surface about the aperture region.

7. The device claim of 1, wherein the optically reflective surface is concave with respect to a focal point located along an axis that extends between the optically reflective surface and the distributed Bragg reflector.

8. The device claim of 1, wherein the distributed Bragg reflector is concave with respect to a focal point located along an axis that extends between the distributed Bragg reflector and the optically reflective surface.

9. The device of claim 1, wherein the optically reflective surface is concave with respect to a first focal point located along an axis that extends between the optically reflective surface and the distributed Bragg reflector, and wherein the distributed Bragg reflector is concave with respect to a second focal point located along the axis.

10. The device of claim 1, the optically reflective surface comprising a reflective material corresponding to one or more of: silver, aluminum, gold, platinum, tungsten, copper, nickel, zinc, or alloys thereof.

11. The device of claim 1, wherein the optically reflective surface corresponds to another distributed Bragg reflector.

12. The device of claim 1, further comprising a micro-lens located above the distributed Bragg reflector about a surface of the aperture region of the device, wherein the micro-lens is configured to collimate light emitted by the distributed Bragg reflector.

13. The device of claim 1, wherein the resonant micro-cavity is arranged to emit light corresponding to desired optical modes while suppressing other optical modes that are not desired.

14. A micro-pixel light emitting diode (LED) device, comprising:
a first contact located about a top contact region in a top portion of the device, wherein the first contact corresponds to one of an n-type material and a p-type material;
a distributed Bragg reflector located about an aperture region of the top portion of the device, wherein the aperture region and the top contact region are substantially different from one another;
a second contact located about a bottom contact region of a bottom portion of the device, wherein the second contact corresponds to one of the n-type material and a p-type material that is different from the first contact;
an optically reflective surface of the second contact;
a quantum well located in a central portion of the device between the top portion and the bottom portion; and
a micro-lens located above the distributed Bragg reflector; and
a resonant micro-cavity formed about the quantum well between the distributed Bragg reflector and the optically reflective surface of the second contact;
wherein:
the distributed Bragg reflector corresponds to a top reflector of resonant micro-cavity;
the optically reflective surface corresponds to a bottom reflector of the resonant micro-cavity;
the optically reflective surface is concave with respect to a first focal point (FP1) located along an axis that between the optically reflective surface and the distributed Bragg reflector;
the distributed Bragg reflector is concave with respect to a second focal point (FP2) located along the axis;
the resonant micro-cavity is configured to promote vertical light propagation and to confine horizontal light propagation;
the resonant micro-cavity is configured to promote emission of desired optical modes and suppress emission of other optical modes that are not desired;
the resonant micro-cavity is configured to emit collimated light at a surface about the aperture region from the distributed Bragg reflector; and
the micro-lens is configured to further collimate the light emitted from the resonant micro-cavity.

15. A display panel device, comprising:
an array of micro-pixel light emitting diode devices, wherein each of the micro-pixel light emitting diode devices comprises:
a first contact located about a top contact region of a top portion of the device, wherein the first contact corresponds to one of an n-type material and a p-type material;
a distributed Bragg reflector located about an aperture region of the top portion of the device, wherein the aperture region and the top contact region are substantially different from one another;
a second contact located about a bottom contact region in a bottom portion of the device, wherein the second contact corresponds to one of the n-type material and a p-type material that is different from the first contact;
an optically reflective surface of the second contact;
a quantum well located in a central portion of the device between the top portion and the bottom portion; and
a resonant micro-cavity formed about the quantum well between the distributed Bragg reflector and the optically reflective surface of the second contact, wherein the distributed Bragg reflector corresponds to a top reflector of the resonant micro-cavity and the optically reflective surface corresponds to a bottom reflector of the resonant micro-cavity, and wherein one or more of the optically reflective surface and the distributed Bragg reflector are concavely shaped such that the resonant micro-cavity promotes vertical light propagation and confines horizontal light propagation.

16. The display panel device of claim 15, wherein each of the micro-pixel light emitting diode devices includes a micro-lens located above the distributed Bragg reflector about a surface of the aperture region of the device, wherein the micro-lens is configured to collimate light emitted by the distributed Bragg reflector.

17. The device of claim 1, wherein the resonant micro-cavity of each of the micro-pixel light emitting diode devices is arranged to emit light corresponding to desired optical modes while suppressing other optical modes that are not desired.

18. The display panel device of claim 15, wherein localized clusters of the micro-pixel light emitting diode devices in the array corresponds to a single pixel of the display panel device.

19. The display panel device of claim 17, wherein each localized clusters includes at least one micro-pixel light emitting diode device corresponding to each of the primary colors of red, green and blue.

20. The display panel device of claim 15, further comprising a single substrate, wherein the array of micro-pixel light emitting diode devices is on the single substrate.
